(19) United States
(12) Patent Application Publication
(10) Pub. No.: US 2015/0025818 A1
(43) Pub. Date: Jan. 22, 2015

(54) SYNCHRONIZED TESTING OF MULTIPLE WIRELESS DEVICES

(71) Applicant: Azimuth Systems, Inc., Acton, MA (US)

(72) Inventors: Deepak Das, Arlington, MA (US); Nandish Chalishazar, Nashua, NH (US); Eric Ely, Goffstown, NH (US)

(73) Assignee: Azimuth Systems, Inc., Acton, MA (US)

(21) Appl. No.: 14/270,456

(22) Filed: May 6, 2014

Related U.S. Application Data
(60) Provisional application No. 61/846,910, filed on Jul. 16, 2013.

(51) Int. Cl. G01R 31/3181; G01R 31/319

(52) U.S. Cl. CPC G01R 31/3181; G01R 31/319
USPC 702/58

(57) ABSTRACT

A plurality of wireless devices which communicate with at least one other device are simultaneously tested using a test regime which includes a plurality of tasks. At least one device synchronizes commencement of each task by all wireless devices. At least one device logs performance measurements of each wireless device for each task. Because the wireless devices begin each task at the same time the resulting log files facilitate per-task performance analysis for each wireless device.

### CROSS-REFERENCE TO RELATED APPLICATIONS

This application claims the benefit of U.S. Provisional Application No. 61/846910 filed Jul. 16, 2013, titled Unified Diagnostics and Analysis for Synchronized Mobile Device Testing, which is incorporated by reference.

### BACKGROUND

The subject matter of this disclosure is generally related to testing of wireless devices. A wide variety of wireless devices are currently in use, and new types are under development. Examples of wireless devices include but are not limited to mobile phones, base stations, wireless routers, cordless phones, personal digital assistants (PDAs), desktop computers, tablet computers, and laptop computers. Testing of a wireless device may be desirable for any of various reasons. For example, testing can be done in the development stage in order to determine whether a prototype wireless device functions as predicted. Testing may also be useful for determining whether production wireless devices perform within specifications, and also for identifying causes of malfunctions.

### SUMMARY

All examples and features mentioned below can be combined in any technically possible way.

In one aspect a method comprises: simultaneously testing a plurality of wireless devices which communicate with at least one other device using a test which includes a plurality of tasks by: synchronizing commencement of each task by all wireless devices; and logging performance measurements of each wireless device for each task. Implementations may include one or more of the following features in any combination. Synchronizing commencement of each task may comprise determining that each of the wireless devices has completed a previously assigned task. Determining that each of the wireless devices has completed a previously assigned task may comprise causing the wireless devices to signal an indication of task completion. Determining that each of the wireless devices has completed a previously assigned task may comprise querying the wireless devices for an indication of task completion. Determining that each of the wireless devices has completed a previously assigned task may comprise passively monitoring wireless device activity. Synchronizing commencement of each task may comprise allowing a predetermined period of time for completion of a previously assigned task before starting a new task. The method may comprise performing at least one task selected from a group consisting of streaming a video, downloading a web page, uploading a photo, uploading a video, performing a voice call, and performing a video call. Logging performance measurements may comprise logging at least one of: power measurements, multiple-input multiple-output correlation, cell information, sector information, location information, data rate, throughput, wireless channel signal quality, and handoff parameters. The method may comprise synchronizing commencement of each task by each wireless device with a computing device having wired connections to the wireless devices. The method may comprise synchronizing commencement of each task by each wireless device with one of the wireless devices that is designated as a master. The method may comprise forming an ad hoc wireless network which includes the wireless devices. The method may comprise synchronizing commencement of each task by each wireless device with an access device. The method may comprise synchronizing commencement of each task by each wireless device with a server that is reached via an access device.

In accordance with another aspect a computer program stored on non-transitory computer-readable memory comprises: instructions which cause a plurality of wireless devices which communicate with at least one other device to be simultaneously tested using a test which includes a plurality of tasks, comprising instructions which synchronize commencement of each task by all wireless devices, and instructions which log performance measurements of each wireless device for each task. Implementations may include one or more of the following features in any combination. The computer program may comprise instructions which determine that each of the wireless devices has completed a previously assigned task. The computer program may comprise instructions which cause the wireless devices to signal an indication of task completion. The computer program may comprise instructions which query the wireless devices for an indication of task completion. The computer program may comprise instructions which passively monitor wireless device activity. The computer program may comprise instructions which allow a predetermined period of time for completion of a previously assigned task before starting a new task. The computer program may comprise instructions which prompt performing at least one task selected from a group consisting of streaming a video, downloading a web page, uploading a photo, uploading a video, performing a voice call, and performing a video call. The performance measurements may comprise at least one of: power measurements, multiple-input multiple-output correlation, cell information, sector information, location information, data rate, throughput, wireless channel signal quality, and handoff parameters. Instructions which synchronize commencement of each task by each wireless device may be executed by a computing device having wired connections to the wireless devices. Instructions which synchronize commencement of each task by each wireless device may be executed by one of the wireless devices that is designated as a master. The computer program may comprise instructions which form an ad hoc wireless network which includes the wireless devices. The instructions which synchronize commencement of each task by each wireless device may be executed by an access device. The instructions which synchronize commencement of each task by each wireless device may be executed by a server that is reached via an access device.

In accordance with another aspect an apparatus comprises: a test system in which a plurality of wireless devices which communicate with at least one other device are simultaneously tested using a test which includes a plurality of tasks, comprising: at least one device which synchronizes commencement of each task by all wireless devices; and at least one device which logs performance measurements of each wireless device for each task. Implementations may include one or more of the following features in any combination. Commencement may be synchronized by determining that all of the wireless devices have completed a previously assigned task prior to prompting all wireless devices to begin another task. The wireless devices may signal an indication of task completion. The wireless devices may be queried for an indication of task completion. Wireless device activity may be passively monitored to determine whether a task has been completed. A predetermined period of time may be allotted for completion of a previously assigned task before starting a new task. The apparatus may include at least one task selected from a group consisting of streaming a video, downloading a web page, uploading a photo, uploading a video, performing a voice call, and performing a video call. The performance measurements may comprise at least one of: power measurements, multiple-input multiple-output correlation, cell information, sector information, location information, data rate, throughput, wireless channel signal quality, and handoff parameters. A computing device having wired connections to the wireless devices may synchronize commencement of each task by all wireless devices. One of the wireless devices that is designated as a master may synchronize commencement of each task by all wireless devices. The wireless devices may form an ad hoc wireless network. An access device may synchronize commencement of each task by all wireless devices. A server that is reached via an access device may synchronize commencement of each task by all wireless devices.

### BRIEF DESCRIPTION OF THE FIGURES

FIG. 1 illustrates synchronized wireless device test logs.

FIGS. 2 and 3 illustrate methods of synchronized testing of DUTs.

FIG. 4 illustrates a conducted testing system.

FIG. 5 illustrates an Over-The-Air (OTA) test system.

FIG. 6 illustrates a tethered, Open-Air (OA) test system.

FIGS. 7 through 9 illustrate untethered OA test systems.

### DETAILED DESCRIPTION

Some aspects, implementations, features and embodiments comprise computer components and computer-implemented steps that will be apparent to those skilled in the art. For example, it should be understood by one of skill in the art that the computer-implemented steps may be stored as computer-executable instructions on a computer-readable medium such as, for example, floppy disks, hard disks, optical disks, Flash ROMS, nonvolatile ROM, and RAM. Furthermore, it should be understood by one of skill in the art that the computer-executable instructions may be executed on a variety of processors such as, for example, microprocessors, digital signal processors, gate arrays, etc. For ease of exposition, not every step or element of the systems and methods described above is described herein as part of a computer system, but those skilled in the art will recognize that each step or element may have a corresponding computer system or software component. Such computer system and/or software components are therefore enabled by describing their corresponding steps or elements (that is, their functionality), and are within the scope of the disclosure. Moreover, the features described herein can be used in any of a wide variety of combinations that are not limited to the illustrated and described examples.

Known wireless device test systems generate data which includes various performance measurements. Although such systems can provide detailed information about the operation of a single Device Under Test (DUT), it is difficult to compare the performance of different DUTs because, for example, it is not always clear from the data when the DUTs begin and finish performing equivalent functions. Moreover, if the DUTs perform the same function at different periods of time then the results may not be meaningfully comparable if the functions are performed under different channel conditions. Consequently, it is difficult to conduct an “apples to apples” comparison of DUTs, particularly in an uncontrolled environment.

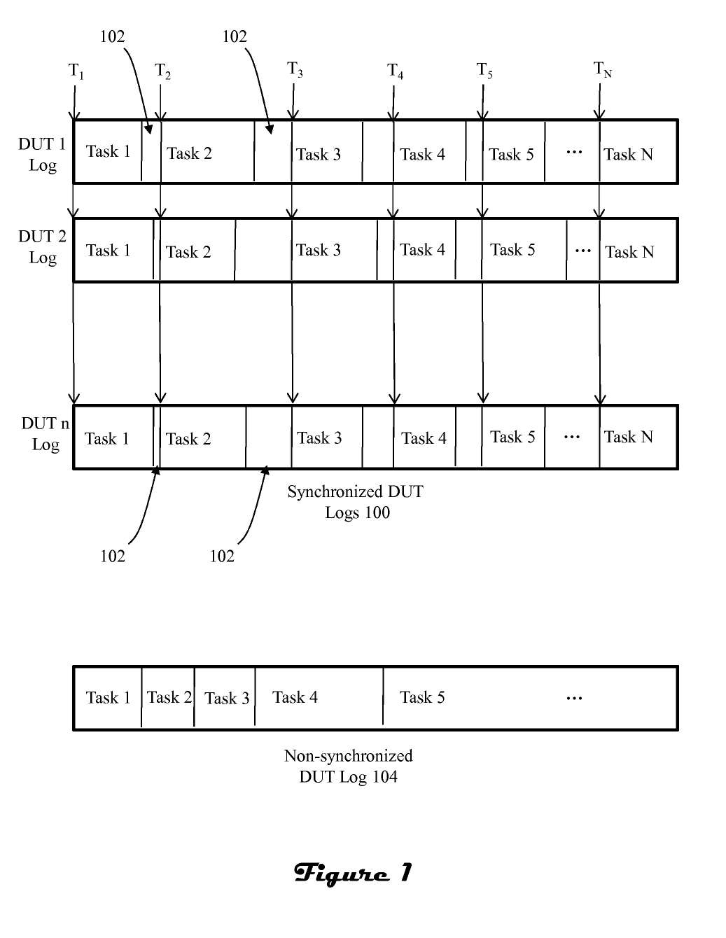

FIG. 1 illustrates a wireless device testing technique which includes generation of wireless device test logs 100 (DUT 1 Log through DUT n Log) which facilitate meaningful “apples to apples” comparison of different DUTs. In accordance with one aspect, multiple DUTs (DUT1 through DUT n) are simultaneously subjected to the same test regime which includes multiple discrete tasks (Task 1 through Task N). Performance of the tasks is synchronized in order to facilitate analysis of the logs 100. More particularly, the start time for performing each test task is synchronized such that each DUT begins the same task at the same time regardless of when the previous task was completed. In the illustrated example start times T₁ through T_{N} correspond to Task 1 through Task N. All of the DUTs in the test are provided adequate time to finish each assigned task before performance of the next task in the test is started. A recognizable quiet interval 102 may be presented between tasks in the log files. The resulting log files (DUT 1 Log through DUT n Log) thus exhibit easily identifiable performance results for each discrete task. For example, it is apparent when each DUT started and completed each task. Consequently, it may be readily apparent if one or more specific tasks had a significant influence on overall performance of one or more of the DUTs. Moreover, the tasks are performed by the DUTs under the same channel conditions because the start times are synchronized, so the comparison is more meaningful relative to an non-synchronized DUT log 104 which would reflect performance of the tasks under potentially different channel conditions because start times would vary and channel conditions change over time.

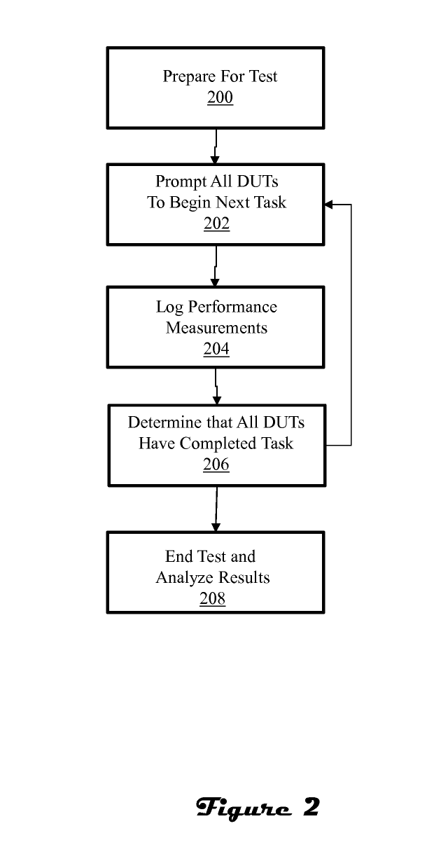

FIG. 2 illustrates a method of synchronized testing of DUTs. An initial step 200 is to prepare for the test. Preparing for the test may include a wide variety of actions depending on the type of test being performed, but generally includes causing the DUTs to begin communication and to become associated with another device in preparation for performance of assigned tasks. In step 202 all of the DUTs in the test are prompted to begin a first assigned task selected from a group of multiple tasks, e.g., Task 1 (FIG. 1). In particular, all of the DUTs (DUT 1 through DUT n) begin performance of the same task at the same time. A wide variety of tasks might be utilized. Examples include, without limitation, streaming a video, downloading a web page, uploading a photo or video, performing a voice call, and performing a video call. Factors which characterize the task as being the same task for all DUTs may be determined by the operator. For example, the task may be to stream the same video from the same server, or to stream the same video from different servers associated with the same server farm, or to stream different videos of equivalent size from servers having equivalent performance. Whatever defining factors are selected, causing the inputs to be equivalent or identical for all DUTs in the test will generally facilitate comparison of the performance of each DUT with the other DUTs in the test by mitigating differences in performance attributable to devices other than the DUT. As indicated in step 204, DUT performance measurements for the assigned task are separately logged for each DUT in the test. For example, a separate log file may be generated for each DUT, e.g., DUT 1 Log through DUT n Log (FIG. 1). The log files may contain a wide variety of performance measurements including but not limited to one or more of power measurements (e.g., interference, noise, signal-to-noise ratio (SNR), received signal strength indicator (RSSI), and multipath Power-Delay-Profile), multiple-input multiple-output (MIMO) correlation, cell information, sector information, location information, data rate, throughput, wireless channel signal quality, and handoff parameters. Logging of performance measurements for each DUT may continue after the task has been completed. A new task is not started until it is determined that all DUTs have completed the assigned task as indicated in step 206. Determining that a DUT has completed the assigned task may include causing the DUT to send an indication of task completion to one or more other devices, e.g., by software loaded on the DUT. The DUT may also be queried by one or more other devices for task completion status. Further, another device may determine independently whether the DUT has completed the task, e.g., by passively monitoring DUT activity via snooping or other techniques. Once it has been determined that all DUTs have completed the assigned task then a new task is selected and assigned. In particular, all DUTs are prompted to begin the same newly assigned task at the same time as indicated in step 202. Steps 202 through 206 continue in an iterative manner until all of the tasks of the test regime have been performed. The test is then ended and the results may be analyzed as indicated in step 208. For example, specific performance measurements for different DUTs may be compared on a per-task basis, and outlier data associated with one or more tasks may be removed from overall performance computations.

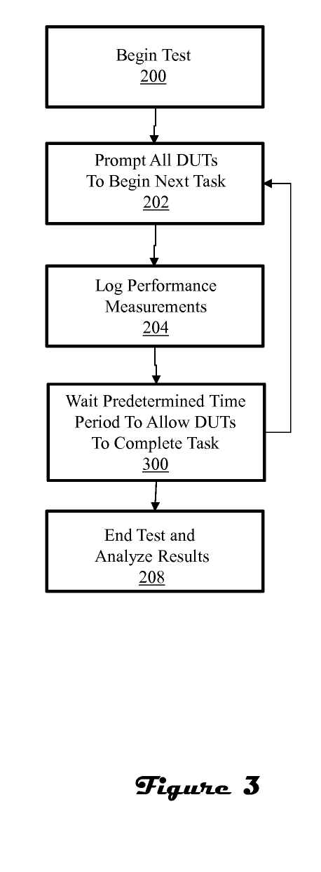

FIG. 3 illustrates another method of synchronized testing of DUTs. Steps with the same reference numbers as those in FIG. 2 (200, 202, 204, and 208) are as described with respect to that figure. This method is substantially similar to the test described with respect to FIG. 2 except that a predetermined period of time is used as indicated in step 300 rather than determining that all DUTs have completed the task. The predetermined period of time may be selected by the operator such that all DUTs should be able to complete the task within that period of time. Different tasks may be expected to require different amounts of time to complete so different periods of time may be associated with different tasks. The time utilized to determine the period between the start of tasks may be real time or test time. For example, the start times may be specific times of day based on a real-time clock or elapsed times based on a counter which is reset at the beginning of each task. Once the predetermined period of time for the currently assigned task has elapsed then another task is selected and all DUTs are prompted to begin the new task at the same time as indicated by step 202. Steps 202, 204 and 300 continue in an iterative manner until all of the tasks have been performed. The test is then ended and the results may be analyzed as indicated in step 208. For example, specific performance measurements for different DUTs may be compared on a per-task basis.

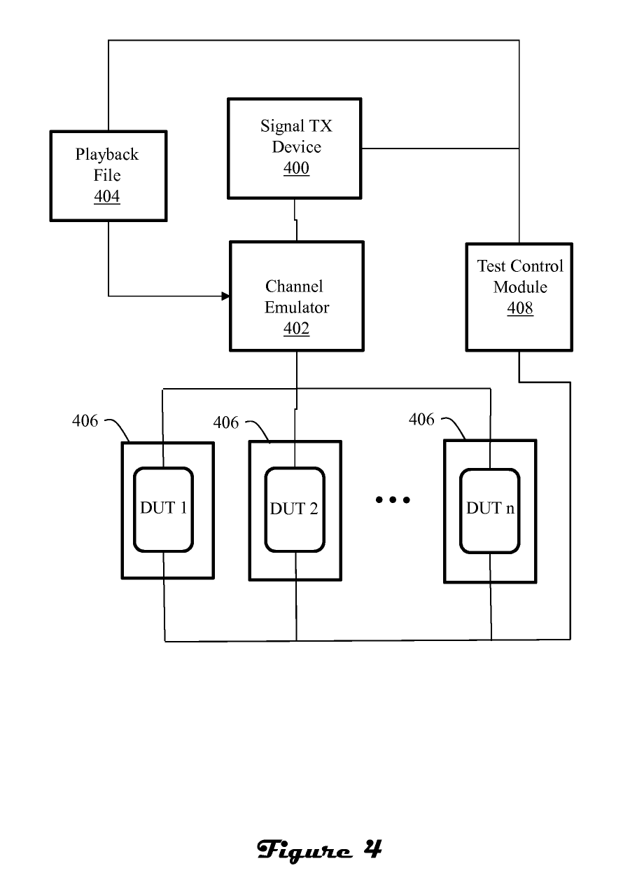

FIG. 4 illustrates a conducted testing system in accordance with the techniques described above. The conducted testing system includes at least one signal transmission device 400, a channel emulator 402, a playback file 404, containers 406, and a test control module 408. Each DUT (DUT 1 through DUT n) is enclosed in a separate one of the EMI-shielded containers 406. The DUT antennas are bypassed with direct wired connections. The containers shield the DUTs from electromagnetic interference (EMI) originating from outside the container. The signal transmission device or devices may include device emulators, real devices such as base stations, access points or controllers, without limitation, or a mix of real devices and device emulators. The channel emulator 402 is used to simulate channel conditions during the test by processing signals transmitted between the signal transmission device 400 and the DUTs. In order to begin a test, the test control module 408 prompts the playback file 404 to be inputted to the channel emulator 402 and prompts the signal transmission device 400 to become associated with the DUTs. The signal transmission device sends signals to the DUTs via the channel emulator 402, and the signal transmission device may also receive signals from the DUTs via the channel emulator. The channel emulator 402 processes the signals which it receives by subjecting those signals to simulated channel conditions specified by the playback file 404. The channel conditions may include, but are not limited to, multipath reflections, delay spread, angle of arrival, power angular spread, angle of departure, antenna spacing, antenna geometry, Doppler from a moving vehicle, Doppler from changing environments, path loss, shadow fading effects, reflections in clusters and external interference such as radar signals, phone transmission and other wireless signals or noise. The playback file 404 may be based on log files from a real network environment, modified log files from a real network environment, or a hypothetical network environment. Performance measurements captured from or by the DUTs, such as data rate or throughput for example and without limitation, may be provided to the test control module 408 for storage (logging) and analysis. The signal transmission device 400 may also provide a signal to the test control module for storage (logging) and analysis. The test control module 408 may synchronize the DUTs, e.g. by determining that all DUTs have completed a task before prompting all DUTs to beginning the next task (step 206, FIG. 2). The test control module might also or alternatively maintain the master clock if synchronization is based on waiting a predetermined period of time to allow the DUTs to complete the task. The master clock could be utilized to measure the predetermined period of time (step 300, FIG. 3).

It should be noted that the test control module 408 is not necessarily used in every configuration. For example, the DUTs and the signal transmission device might generate their own log files. A distributed program, or coordinated programs running on different devices, could be used to implement the methods described above, including but not limited to step 206 of FIG. 2 and step 300 of FIG. 3.

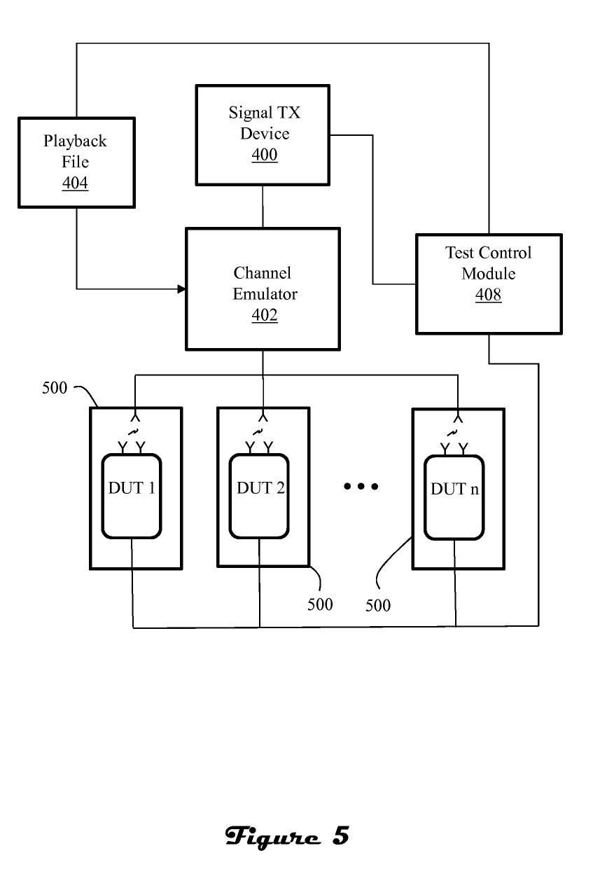

FIG. 5 illustrates an Over-The-Air (OTA) test system in accordance with the techniques described above. The OTA test system includes at least one signal transmission device 400, a channel emulator 402, a playback file 404, OTA test chambers 500, and a test control module 408. Each DUT (DUT 1 through DUT n) is enclosed in a separate OTA test chamber 500 such as a reverberation chamber or anechoic chamber. The OTA test chamber provides a controlled environment in which the DUT can be tested in its native state. Antennas mounted within the chamber are used to transmit signals to the DUT from the signal transmission device. Apart from the OTA environment within the test chambers, the system operates in substantially the same manner as the conducted testing system described with reference to FIG. 4, with common elements performing the same or similar functions. The test control module 408 may synchronize the DUTs, e.g. by determining that all DUTs have completed a task before prompting all DUTs to begin the next task. The test control module might also maintain the master clock if synchronization is based on waiting a predetermined period of time to allow the DUTs to complete the task. If the test control module is not used then the DUTs and the signal transmission device might generate their own log files. A distributed program, or coordinated programs running on different devices, could be used to implement the methods described above, including but not limited to step 206 of FIG. 2 and step 300 of FIG. 3.

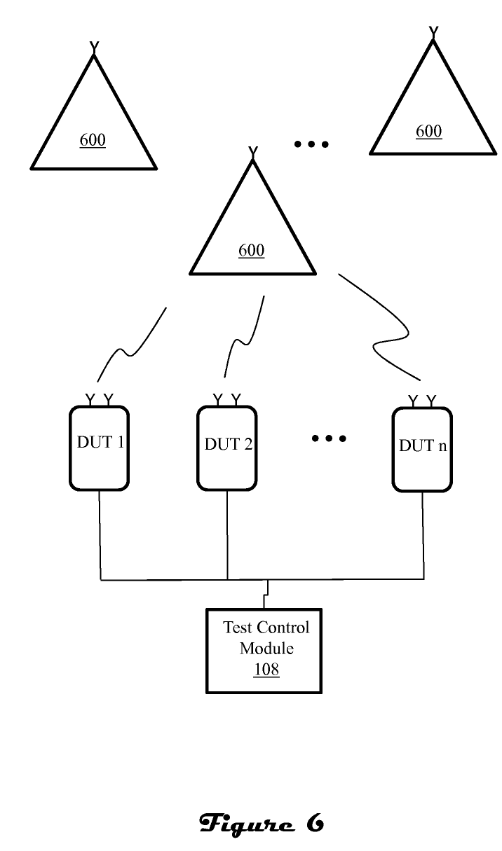

FIG. 6 illustrates a tethered, Open-Air (OA) test system in accordance with the techniques described above. OA testing of wireless devices may be performed by moving the DUTs (DUT 1 through DUT n) together within a partly or completely uncontrolled environment while measuring the various performance parameters which are stored in the log files (DUT 1 Log through DUT n Log, FIG. 1). For example, the DUTs may be moved through a real access network which includes various access devices 600 such as base stations and wireless access points with which the DUTs may associate and communicate. The access devices may be connected to a wired network through which various servers and other devices can be accessed. The test control module 108 may synchronize the DUTs, e.g. by determining that all DUTs have completed a task before prompting all DUTs to beginning the next task. The test control module might also maintain the master clock if synchronization is based on waiting a predetermined period of time to allow the DUTs to complete the task. A distributed program, or coordinated programs running on different devices, could be used to implement the methods described above, including but not limited to step 206 of FIG. 2 and step 300 of FIG. 3.

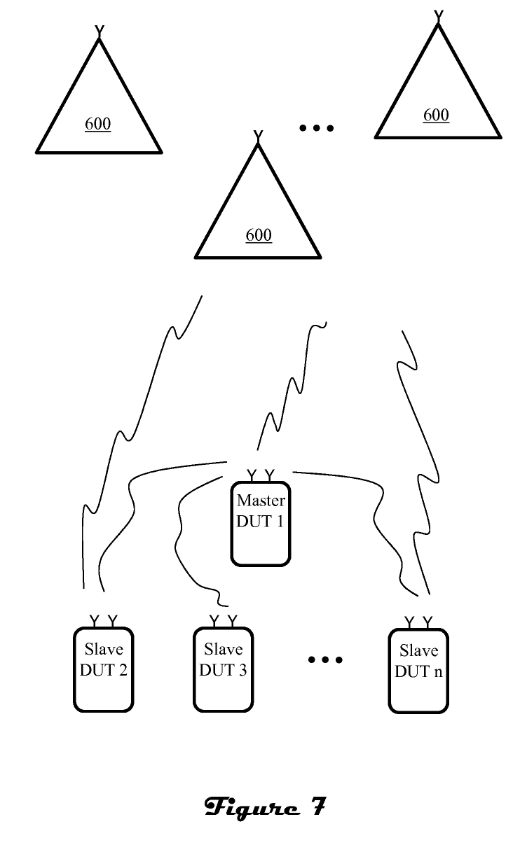

FIG. 7 illustrates an untethered OA test system in accordance with the techniques described above. The DUTs (DUT 1 through DUT n) operate together within a partly or completely uncontrolled environment while various DUT performance parameters are measured and stored in the log files (DUT 1 Log through DUT n Log, FIG. 1). For example, the DUTs may be moved through a real network which includes various access devices 600 such as base stations and wireless access points with which the DUTs may associate and communicate. The access devices may be connected to a wired network through which various servers and other devices can be accessed. One of the DUTs, e.g., DUT 1, is designated as the master device. The other DUTs, e.g., DUT 2 through DUT n, are designated as slave devices. The master device is equipped with a master control program that controls synchronization among the DUTs, and the slave devices may be equipped with slave control programs that communicate with the master program. For example, the DUTs may form an ad hoc local wireless network via which the programs can communicate. The master device may synchronize the DUTs by determining that all DUTs have completed a task before prompting all DUTs to begin the next task. The master device might also or alternatively maintain a master clock. If synchronization is based on waiting a predetermined period of time to allow the DUTs to complete the task then packets with appropriate timestamps, markers or time pulses may be broadcast to the slave devices from the master device via the ad hoc network to synchronize task start times. The DUTs may generate their own log files. The program or programs running on the DUTs implement the methods described above, including but not limited to step 206 of FIG. 2 and step 300 of FIG. 3.

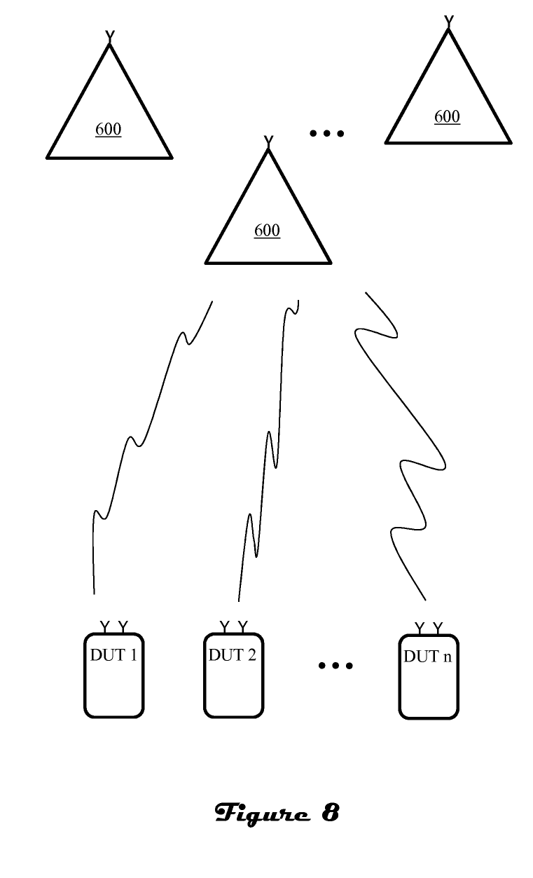

FIG. 8 illustrates another untethered OA test system in accordance with the techniques described above. The system is substantially similar to the system described with respect to FIG. 7 except that there are no master device and slave device designations, and synchronization is controlled by one or more network access devices 600. One or more of the network access devices may synchronize the DUTs by determining that all DUTs have completed a task before prompting all DUTs to begin the next task. One or more of the network access devices might also or alternatively maintain a master clock. If synchronization is based on waiting a predetermined period of time to allow the DUTs to complete the task then packets with appropriate timestamps, markers or time pulses may be broadcast to the DUTs from at least one of the network access devices to synchronize task start times. The DUTs may generate their own log files. A program or programs running on the DUTs may help implement the methods described above, including but not limited to step 206 of FIG. 2 and step 300 of FIG. 3.

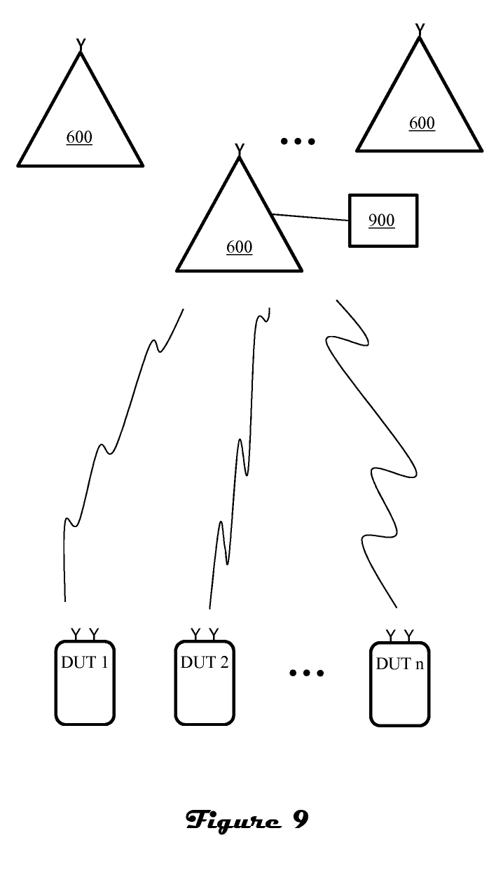

FIG. 9 illustrates another untethered OA test system in accordance with the techniques described above. The system is substantially similar to the system described with respect to FIG. 8 except that a network device 900 other than an access device 600 synchronizes the DUTs (DUT 1 through DUT n). For example, the DUTs may register with a network device such as a server that synchronizes the DUTs by determining that all DUTs have completed a task before prompting all DUTs to begin the next task. The server might also or alternatively maintain a master clock. If synchronization is based on waiting a predetermined period of time to allow the DUTs to complete the task then packets with appropriate timestamps, markers or time pulses may be broadcast to the DUTs from the server to synchronize task start times. The DUTs may maintain their own log files. A program or programs running on the DUTs may help implement the methods described above, including but not limited to step 206 of FIG. 2 and step 300 of FIG. 3.

In the examples described above and variations thereof, robustness in terms of periodic or trigger-based timing re-synchronization, graceful behavior in the cases of loss of timing synchronization, failure reporting and ability to switch between modes, as appropriate, may be provided. Graceful behavior in the cases of loss of timing synchronization may include use of wait periods between tests, wait periods followed by retries to acquire timing synchronization, appropriate warning to the operator and ability to free-run without timing synchronization for a meaningful duration or up to a certain pre-defined event.

A number of implementations have been described. Nevertheless, it will be understood that additional modifications may be made without departing from the scope of the inventive concepts described herein, and, accordingly, other aspects, implementations, features and embodiments are within the scope of the following claims.

What is claimed is:

1. A method comprising:
simultaneously testing a plurality of wireless devices which communicate with at least one other device using a test which includes a plurality of tasks by:
synchronizing commencement of each task by all wireless devices; and
logging performance measurements of each wireless device for each task.

2. The method of claim 1 wherein synchronizing commencement of each task comprises determining that each of the wireless devices has completed a previously assigned task.

3. The method of claim 2 wherein determining that each of the wireless devices has completed a previously assigned task comprises causing the wireless devices to signal an indication of task completion.

4. The method of claim 2 wherein determining that each of the wireless devices has completed a previously assigned task comprises querying the wireless devices for an indication of task completion.

5. The method of claim 2 wherein determining that each of the wireless devices has completed a previously assigned task comprises passively monitoring wireless device activity.

6. The method of claim 1 wherein synchronizing commencement of each task comprises allowing a predetermined period of time for completion of a previously assigned task before starting a new task.

7. The method of claim 1 further comprising performing at least one task selected from a group consisting of streaming a video, downloading a web page, uploading a photo, uploading a video, performing a voice call, and performing a video call.

8. The method of claim 1 wherein logging performance measurements comprises logging at least one of: power measurements, multiple-input multiple-output correlation, cell information, sector information, location information, data rate, throughput, wireless channel signal quality, and handoff parameters.

9. The method of claim 1 further comprising synchronizing commencement of each task by each wireless device with a computing device having wired connections to the wireless devices.

10. The method of claim 1 further comprising synchronizing commencement of each task by each wireless device with one of the wireless devices that is designated as a master.

11. The method of claim 10 further comprising forming an ad hoc wireless network which includes the wireless devices.

12. The method of claim 1 further comprising synchronizing commencement of each task by each wireless device with an access device.

13. The method of claim 1 further comprising synchronizing commencement of each task by each wireless device with a server that is reached via an access device.

14. A computer program stored on non-transitory computer-readable memory comprising:
instructions which cause a plurality of wireless devices which communicate with at least one other device to be simultaneously tested using a test which includes a plurality of tasks, comprising instructions which synchronize commencement of each task by all wireless devices, and instructions which log performance measurements of each wireless device for each task.

15. The computer program of claim 14 comprising instructions which determine that each of the wireless devices has completed a previously assigned task.

16. The computer program of claim 15 comprising instructions which cause the wireless devices to signal an indication of task completion.

17. The computer program of claim 15 comprising instructions which query the wireless devices for an indication of task completion.

18. The computer program of claim 15 comprising instructions which passively monitor wireless device activity.

19. The computer program of claim 14 comprising instructions which allow a predetermined period of time for completion of a previously assigned task before starting a new task.

20. The computer program of claim 14 comprising instructions which prompt performing at least one task selected from a group consisting of streaming a video, downloading a web page, uploading a photo, uploading a video, performing a voice call, and performing a video call.

21. The computer program of claim 14 wherein the performance measurements comprise at least one of: power measurements, multiple-input multiple-output correlation, cell information, sector information, location information, data rate, throughput, wireless channel signal quality, and handoff parameters.

22. The computer program of claim 14 wherein instructions which synchronize commencement of each task by each wireless device are executed by a computing device having wired connections to the wireless devices.

23. The computer program of claim 14 wherein instructions which synchronize commencement of each task by each wireless device are executed by one of the wireless devices that is designated as a master.

24. The computer program of claim 23 further comprising instructions which form an ad hoc wireless network which includes the wireless devices.

25. The computer program of claim 14 wherein instructions which synchronize commencement of each task by each wireless device are executed by an access device.

26. The computer program of claim 14 wherein instructions which synchronize commencement of each task by each wireless device are executed by a server that is reached via an access device.

27. Apparatus comprising:
a test system in which a plurality of wireless devices which communicate with at least one other device are simultaneously tested using a test which includes a plurality of tasks, comprising:
at least one device which synchronizes commencement of each task by all wireless devices; and
at least one device which logs performance measurements of each wireless device for each task.

28. The apparatus of claim 27 in which commencement is synchronized by determining that all of the wireless devices have completed a previously assigned task prior to prompting all wireless devices to begin another task.

29. The apparatus of claim 28 in which the wireless devices signal an indication of task completion.

30. The apparatus of claim 28 in which the wireless devices are queried for an indication of task completion.

31. The apparatus of claim 28 wherein wireless device activity is passively monitored to determine whether a task has been completed.

32. The apparatus of claim 27 wherein a predetermined period of time is allotted for completion of a previously assigned task before starting a new task.

33. The apparatus of claim 27 including at least one task selected from a group consisting of streaming a video, downloading a web page, uploading a photo, uploading a video, performing a voice call, and performing a video call.

34. The apparatus of claim 27 wherein the performance measurements comprise at least one of: power measurements, multiple-input multiple-output correlation, cell information, sector information, location information, data rate, throughput, wireless channel signal quality, and handoff parameters.

35. The apparatus of claim 27 wherein a computing device having wired connections to the wireless devices synchronizes commencement of each task by all wireless devices.

36. The apparatus of claim 27 wherein one of the wireless devices that is designated as a master synchronizes commencement of each task by all wireless devices.

37. The apparatus of claim 36 wherein the wireless devices form an ad hoc wireless network.

38. The apparatus of claim 27 wherein an access device synchronizes commencement of each task by all wireless devices.

39. The apparatus of claim 27 wherein a server that is reached via an access device synchronizes commencement of each task by all wireless devices.
